(19) United States
(12) Patent Application Publication
(10) Pub. No.: US 2010/0316467 A1
(43) Pub. Date: Dec. 16, 2010

(54) SUBSTRATE STORAGE FACILITY

(76) Inventors: Mareto Ishibashi, Tokyo (JP); Toshitaka Oono, Tokyo (JP)

Correspondence Address: OSTROLENK FABER GERB & SOFFEN, 1180 AVENUE OF THE AMERICAS, NEW YORK, NY, 100368403, US

(21) Appl. No.: 12/446,027

(22) PCT Filed: Oct. 16, 2007
(86) PCT No.: PCT/JP2007/070142

§ 371 Date: Apr. 17, 2009

(30) Foreign Application Priority Data
Oct. 18, 2006 (JP) 2006-284131

(51) Int. Cl. H01L 21/677; H01L 21/673; B65G 1/04; B65G 49/07

(52) U.S. Cl. 414/217.1; 257/E21.001

(57) ABSTRACT

A substrate storage facility comprises a multilevel shelf, on which a plurality of cassettes with airtight covers accommodating a plurality of substrates can be placed; a substrate transport portion, moveably positioned on the front-face side of the multilevel shelf, which opens and closes the airtight covers of the cassettes with airtight covers placed on the multilevel shelf, and which transports the substrates between cassettes with airtight covers; and, a cassette transport portion, moveably positioned on the rear-face side of the multilevel shelf, which carries cassettes with airtight covers into and out of all the cassette placement positions of the multilevel shelf. By means of this substrate storage facility, interchange processing of substrates accommodated in cassettes, as well as carrying in and out of cassettes when appropriate, can be performed.

### TECHNICAL FIELD

This invention relates to a substrate storage facility. This application claims priority from Japanese Patent Application No. 2006-284131, filed Oct. 18, 2006, the contents of which are incorporated herein by reference.

### BACKGROUND ART

In the prior art, technology is known for transportation and storage in automated warehouses of individual cassettes, each of which accommodates a plurality of semiconductor wafers, glass plates, and other substrates, in a cleanroom in which semiconductor devices and FPDs (flat panel displays) are manufactured. For example, standardized cassettes called FOUPs (Front-Opening Unified Pods) are used in the case of semiconductor wafers.

Methods in which a plurality of substrates are accommodated by a cassette for transport are well-suited to few-varieties mass production. However, in the case of many-varieties mass production in which different processing is performed for each substrate, only substrates to be subjected to the same processing have to be stored in a given cassette, so that the number of cassettes storing only a certain number of substrates increases, and there is the problem that processing efficiency in various processing apparatuses, as well as efficiency of transportation by transportation apparatus, and efficiency of storage of automated warehouses, are decreased.

In order to resolve such problems, technology (for so-called lot formation equipment) such as that disclosed in Patent Reference 1 has been proposed, wherein, by interchanging (sorting) substrates between cassettes in an automated warehouse, the number of substrates stored in one cassette can be increased, and the processing efficiency of various processing apparatuses, and the efficiency of storage in the automated warehouse, are improved.

Patent Reference 1: Japanese Unexamined Patent Application, First Publication No. 2001-31212

However, in the case of the technology disclosed in Patent Reference 1, substrate interchange processing can only be performed in locations in which an opener, which removes an airtight cover installed on a cassette, is positioned.

Moreover, locations for carrying cassettes into and out of an automated warehouse are limited, and locations at which substrate interchange processing is performed, and locations for carrying cassettes in and out, may overlap.

For these reasons, when carrying a cassette which accommodates a desired substrate out of an automated warehouse, situations occur in which it is necessary to wait until completion of substrate interchange processing. Similarly, a wait time also occurs when carrying a cassette into an automated warehouse. Hence there is the problem of a possible decline in the efficiency of manufacture of semiconductor devices and the like.

This invention was devised in light of the above-described circumstances, and has as an object the proposal of an automated warehouse in which interchange processing of substrates accommodated in cassettes is performed, and which is capable of carrying cassettes in and out when appropriate.

### DISCLOSURE OF THE INVENTION

In order to resolve the above problems, a substrate storage facility of this invention adopts the following means.

A substrate storage facility of this invention comprises a multilevel shelf, on which a plurality of cassettes with airtight covers accommodating a plurality of substrates can be placed; a substrate transport portion, moveably positioned on the front-face side of the multilevel shelf, which opens and closes the airtight covers of the cassettes with airtight covers placed on the multilevel shelf, and which transports the substrates between cassettes with airtight covers; and, a cassette transport portion, moveably positioned on the rear-face side of the multilevel shelf, which carries cassettes with airtight covers into and out of all the cassette placement positions of the multilevel shelf.

The multilevel shelf comprises a rear-face partition, partitioning into a first space in which the cassette transport portion is positioned, and a second space in which the substrate transport portion is positioned; rear-face apertures, formed at positions in opposition to the various cassette placement positions in the rear-face partition, via which the cassettes with airtight covers are carried in and out; and, first airtight doors, which block the rear-face apertures.

Further, the first space and the second space are maintained in different air states.

Further, the multilevel shelf comprises a front-face partition, partitioning into a third space in which the multilevel shelf is positioned and a fourth space into which the substrate transport portion is positioned; front-face apertures, formed at positions in opposition to the various cassette placement positions in the front-face partition, via which substrates are carried into and out from the cassettes with airtight covers; and, second airtight doors, which block the front-face apertures.

Further, the cassettes with airtight covers are placed on the multilevel shelf such that the body of the cassette with an airtight cover is fixed in close contact with the inner-peripheral edge of the front-face aperture.

Further, the third space and the fourth space are maintained in different air states.

Further, the multilevel shelf has internal partitions which demarcate the cassette accommodation positions, individually or into a plurality.

Further, the multilevel shelf comprises an air purge mechanism which performs air purges of the third space when a cassette with an airtight cover is carried into or out of the multilevel shelf.

Further, multilevel shelves are arranged in opposition on either side of the substrate transport portion, and such that a cassette transport portion is arranged for each of the multilevel shelves.

By means of this invention, the following advantageous results are obtained.

Because cassettes with airtight covers can be carried directly in and out at each of the cassette placement positions of the multilevel shelves, cassettes with airtight covers for which substrate interchange processing by a substrate transport portion has been completed can be carried out from the multilevel shelves by a cassette transport portion when appropriate. And, a cassette with airtight cover for which substrate interchange processing is to be performed can be carried into a cassette placement position not occupied by a cassette with an airtight cover.

And, substrate interchange processing by a substrate transport portion, and carrying-in and carrying-out processing of a cassette with an airtight cover by a cassette transport portion, can each be performed separately, independently, and simultaneously, so that substrate interchange processing can be performed efficiently, and at the same time carrying-in/out processing of cassettes with airtight covers can also be performed efficiently.

Further, even when substrate interchange processing by a substrate transport portion and carrying-in processing and carrying-out processing of cassettes with airtight covers by a cassette transport portion are performed simultaneously, the possibility of adhesion of contaminants to substrates can be kept low, so that declines in manufacturing yields can be avoided.

### BRIEF DESCRIPTION OF THE DRAWINGS

FIG. 1 is a top view showing in summary the configuration of the wafer storage facility of an embodiment of the invention;

FIG. 2 is a front view (the view of arrow P in FIG. 1) of a multilevel shelf of a wafer storage facility.

FIG. 3 is a side view of a wafer storage facility.

FIG. 4 is a rear view (the view of arrow Q in FIG. 1) of a multilevel shelf of a wafer storage facility.

FIG. 5 is a perspective view showing a wafer-accommodating cassette.

FIG. 6 is a top view showing a wafer loader and opener of a wafer transport portion.

FIG. 7 is a schematic diagram showing a front-face aperture.

### DESCRIPTION OF SYMBOLS

1 STORAGE FACILITY FOR WAFERS (SUBSTRATE STORAGE FACILITY)
2 STORAGE FACILITY MAIN UNIT
5 MULTILEVEL SHELF
5a FRONT FACE
5b REAR FACE
5c CASSETTE PLACEMENT POSITION
10 PARTITION
12 REAR-FACE PARTITION
13 REAR-FACE APERTURE
14 SHUTTER (FIRST AIRTIGHT DOOR)
15 FRONT-FACE PARTITION
16 FRONT-FACE APERTURE
17 SHUTTER (SECOND AIRTIGHT DOOR)
18 INTERNAL PARTITION
20 WAFER TRANSPORT PORTION (SUBSTRATE TRANSPORT PORTION)
24 WAFER LOADER
25 OPENER
30 CASSETTE TRANSPORT PORTION
50 CONTROL PORTION
80 WAFER-ACCOMMODATING CASSETTE (CASSETTE WITH AIRTIGHT COVER)
81 CONTAINER BODY
83 AIRTIGHT COVER
S1 FIRST SPACE
S2 SECOND SPACE
S3 THIRD SPACE
S4 FOURTH SPACE
W WAFER (SUBSTRATE)

### BEST MODE FOR CARRYING OUT THE INVENTION

Below, an embodiment of a substrate storage facility 1 of the invention is explained, referring to the drawings.

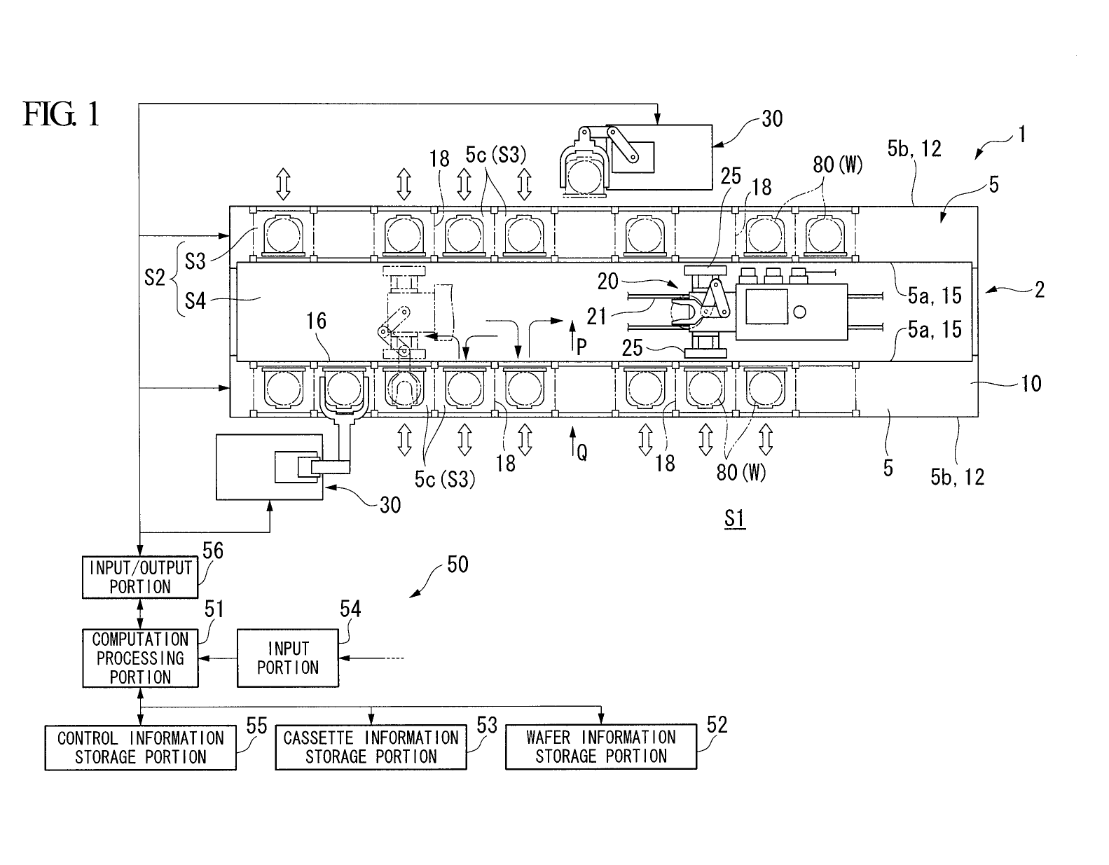

FIG. 1 is a top view showing in summary the configuration of the wafer storage facility 1 of an embodiment of the invention.

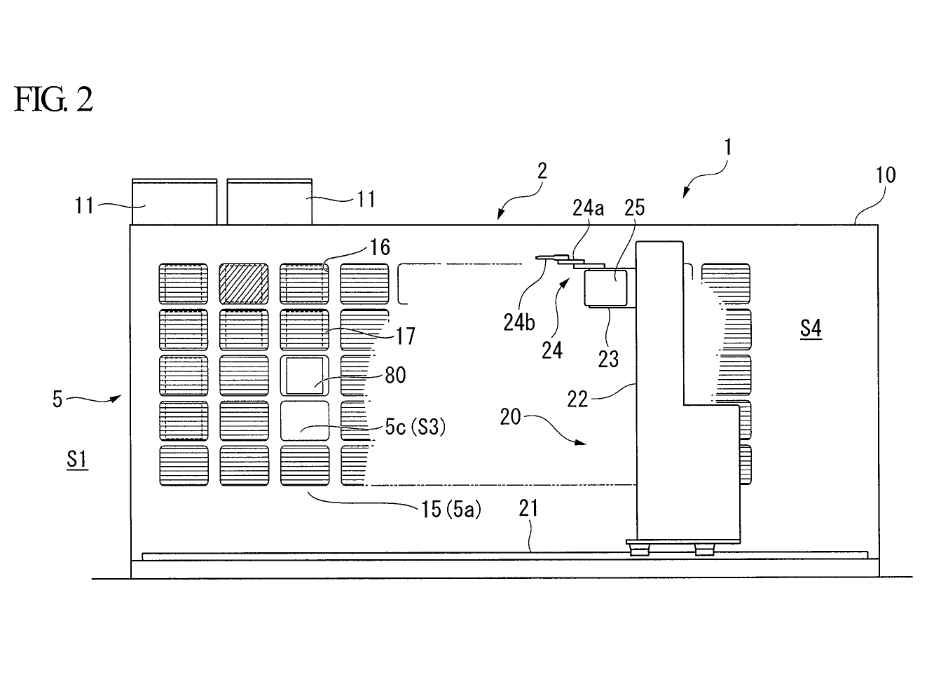

FIG. 2 is a front view (the view of arrow P in FIG. 1) of a multilevel shelf 5 of the wafer storage facility 1.

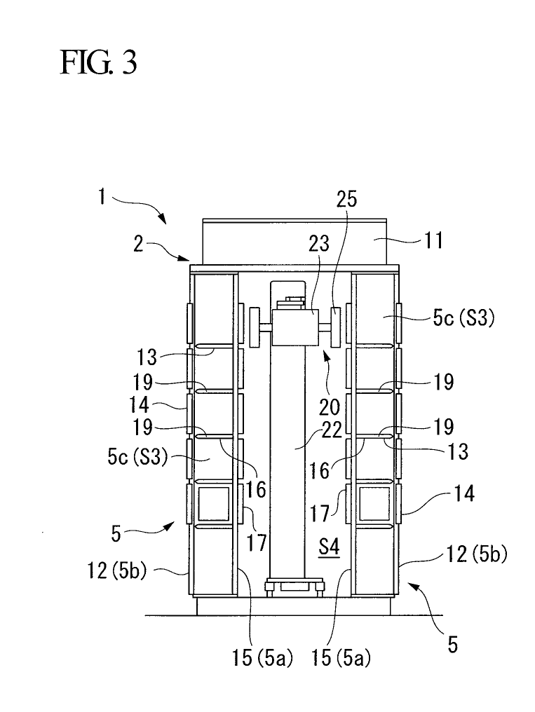

FIG. 3 is a side view of the wafer storage facility 1.

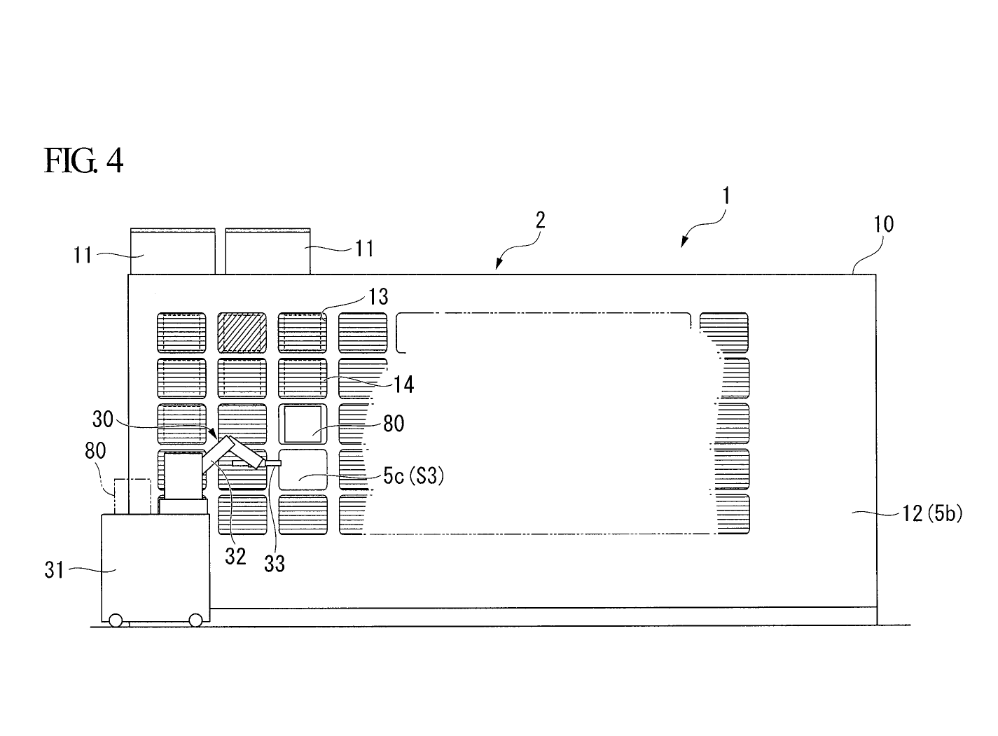

FIG. 4 is a rear view (the view of arrow Q in FIG. 1) of a multilevel shelf 5 of the wafer storage facility 1.

The wafer storage facility 1 comprises two multilevel shelves 5, 5, positioned in parallel and in opposition with a prescribed interval therebetween; a wafer transport portion 20, positioned between the two multilevel shelves 5, 5; cassette transport portions 30, positioned on the outsides of the two multilevel shelves 5, 5; and a control portion 50, which executes comprehensive control.

A plurality of wafer-accommodating cassettes 80, described below, can be placed on the two multilevel shelves 5, 5, and cassette placement positions 5c, at which wafer-accommodating cassettes 80 can be placed, are demarcated in an array pattern so as to be arranged at equal intervals in the horizontal direction and in the vertical direction.

And, the two multilevel shelves 5, 5 are arranged in parallel and in opposition with a prescribed interval therebetween.

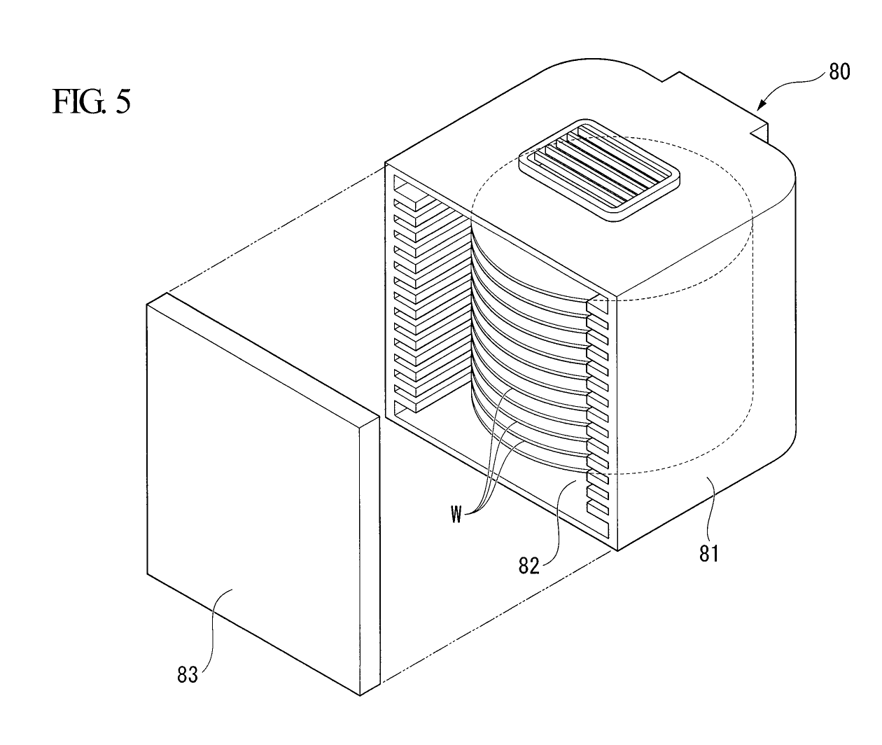

FIG. 5 is a perspective view showing a wafer-accommodating cassette 80.

The wafer-accommodating cassette 80 is a container which accommodates a stack of a plurality of wafers W, with a fixed interval therebetween, and has a container body 81, in which is formed a front-face aperture 82 through which wafers W can be removed and inserted, and an airtight cover 83 which blocks the front-face aperture 82. For example, a plurality of wafers W of diameter 200 mm and 300 mm can be accommodated in a horizontal state. Air in the internal space is maintained in a highly clean state (high degree of cleanliness). Specifically, class 1 air cleanliness is maintained.

As the wafer-accommodating cassette 80, a FOUP (Front-Opening Unified Pod), stipulated in SEMI standards, can be used.

Each wafer-accommodating cassette 80 is placed on the multilevel shelves 5, 5 such that the front-face aperture 82 (airtight cover 83) is facing the side of the wafer transport portion 20 (the front-face sides 5a, 5a of the multilevel shelves 5, 5).

The wafer transport portion 20 comprises a columnar traveling portion 22 which travels on a rail 21 laid on the floor between the two multilevel shelves 5, 5 along the two multilevel shelves 5, 5, a main portion 23, connected to the traveling portion 22 and which can move in the vertical direction, and a wafer loader 24 and opener 25 connected to the main portion 23.

The wafer transport portion 20 can move the wafer loader 24 and opener 25 in the directions of two directions along the front faces 5a, 5a of the multilevel shelves 5, 5, by means of position control of the traveling portion 22 and the main portion 23.

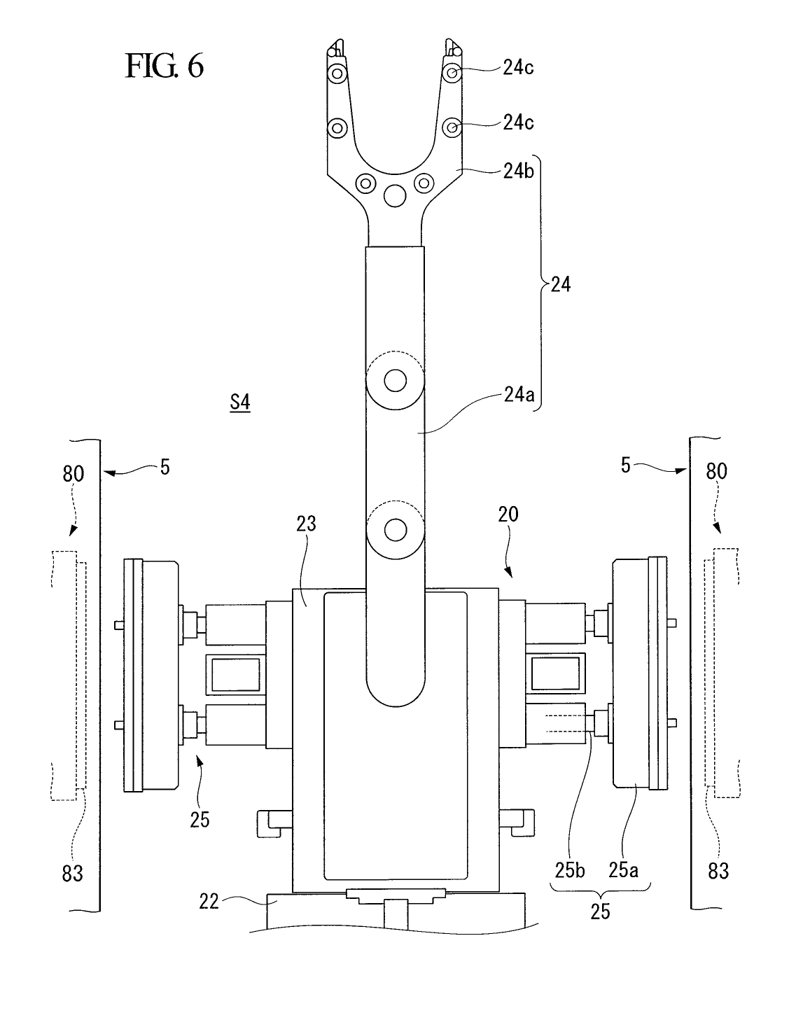

FIG. 6 is a top view showing the wafer loader 24 and opener 25 of the wafer transport portion 20.

The wafer loader 24 is a horizontally-articulated robot, comprising an arm portion 24a having three arms one end of which is connected to the upper face of the main portion 23, and a hand 24b connected to the tip of the arm portion 24a. The hand 24b is configured such that wafers W are placed on and held by the hand 24b without contact, by blowing air from air-blowing openings 24c. The hand 24b need not be a contact-free type hand.

The opener 25 opens and closes the airtight covers 83 of wafer-accommodating cassettes 80, and comprises a gripping portion 25a which suction-clamps or grasps an airtight cover 83, and a moveable portion 25b which can move the gripping portion 25a parallel to the horizontal direction.

Openers 25 are provided on two side faces of the main portion 23, that is, on the two faces opposing the multilevel shelves 5, 5. That is, one opener 25 is positioned opposing each of the multilevel shelves 5.

Each of the openers 25 opens and closes the airtight covers 83 of wafer-accommodating cassettes 80 placed on the respective opposing multilevel shelf 5.

Returning to FIG. 1 through FIG. 4, the cassette transport portions 30 carry wafer-accommodating cassettes 80, placed on the two multilevel shelves 5, 5, into and out of the rear-face sides 5b, 5b of the two multilevel shelves 5, 5.

A plurality of cassette transport portions 30 can be used according to the number of wafer-accommodating cassettes 80 which are carried in and out.

The cassette transport portions 30 comprise an unmanned transport vehicle 31, an articulated robot 32 placed on the unmanned vehicle 31, and a hand 33 connected to the articulated robot 32.

An unmanned vehicle 31 can move along the rear faces 5b, 5b of the two multilevel shelves 5, 5, and can move in an arbitrary direction away from the rear faces 5b, 5b of the two multilevel shelves 5, 5.

An articulated robot 32 is configured so as to enable the hand 33 connected to the tip of the arm to move toward each of the cassette placement positions 5c of the multilevel shelves 5, 5. For example, the robot may be a horizontally-articulated robot, a vertically-articulated robot, an orthogonal robot, or the like.

The hand 33 grips a wafer-accommodating cassette 80 placed at a cassette placement position 5c on the multilevel shelves 5, 5 from the rear-face side (the side opposite the front-face aperture 82).

That is, the cassette transport portion 30 can carry an arbitrary wafer-accommodating cassette 80 into and out of the multilevel shelves 5, 5, by moving the hand 33 to an arbitrary cassette placement position 5c on the rear faces 5b, 5b of the multilevel shelves 5, 5 and then gripping, through position control of the unmanned vehicle 31 and the articulated robot 32.

The control portion 50 comprises an input portion 51, to which information relating to each of the wafers W and each of the wafer-accommodating cassettes 80 is input; a wafer information storage portion 52, which stores input information relating to wafers W; a cassette information storage portion 53, which stores input information relating to wafer-accommodating cassettes 80; a computation processing portion 54, which computes movement instruction information for the wafer transport portion 20 and cassette transport portions 30; a control information storage portion 55, which stores movement instruction information, computed by the computation processing portion 54, for the wafer transport portion 20 and cassette transport portions 30; and, an input/output portion 56, which outputs movement instruction information read from the control information storage portion 55 to the wafer transport portion 20 and cassette transport portions 30 and the like, and to which information is input from the wafer transport portion 20, cassette transport portions 30, and the like.

Information relating to wafers W includes ID numbers for wafers W, information on various processing to be performed on each wafer W, information on the history of processing already performed on wafers, and the like.

Information relating to wafer-accommodating cassettes 80 includes ID numbers of wafer-accommodating cassettes 80, position information for the cassette placement position 5c at which a wafer-accommodating cassette 80 is placed, wafer accommodation conditions, and the like.

And, in the computation processing portion 54, information input from the input portion 51 is used to decide the wafers W, among the wafers W accommodated by the plurality of wafer-accommodating cassettes 80 placed on the multilevel shelves 5, 5, for which to perform sorting processing (interchange processing) by means of the wafer transport portion 20.

Also, in the computation processing portion 54, wafer-accommodating cassettes 80 to be carried out from the multilevel shelves 5, 5, and wafer-accommodating cassettes 80 to be carried into the multilevel shelves 5, 5, by the cassette transport portions 30 are decided, from among the plurality of wafer-accommodating cassettes 80 placed on the multilevel shelves 5, 5.

The two multilevel shelves 5, 5 and the wafer transport portion 20 are positioned within the sealed storage facility main unit 2, and a state of isolation from the space (hereafter called the first space S1) in which the cassette transport portions 30 and the like are arranged. The two multilevel shelves 5, 5 and the wafer transport portion 20 are surrounded by a partition 10, and an interior space (hereafter called the second space S2) of the storage facility main unit 2 is formed.

On the upper face of the storage facility main unit 2 is provided a filter unit 11; by this means, the air cleanness (cleanliness) of the second space S2 is maintained at a higher level than in the first space S1. For example, the air cleanliness of the first space S1 is approximately class 100, while the air cleanliness of the second space S2 is approximately class 1.

Moreover, the second space S2 is maintained at a somewhat higher pressure than in the first space S1.

On the rear faces of the multilevel shelves 5, 5 are arranged rear-face partitions 12, which are portions of the partition 10.

At positions in the rear-face partitions 12 corresponding to each of the cassette placement positions 5c of the multilevel shelves 5, 5 are formed rear-face apertures 13 for the insertion and removal of each of the wafer-accommodating cassettes 80. And, on each of the rear-face apertures 13 is provided a shutter 14; since the rear-face apertures 13 are blocked by means of these shutters 14, the first space S1 and second space S2 are partitioned, and airtightness is maintained.

The shutters 14 are opened and closed according to instructions from the control portion 50.

On the front faces of the multilevel shelves 5, 5 are arranged, in close contact, front-face partitions 15. By means of these front-face partitions 15, the internal space (second space S2) of the storage facility main unit 2 is partitioned from the space in which the multilevel shelves 5, 5 are arranged (hereafter called the third space S3) and from the space in which the wafer transport portion 20 is arranged (hereafter called the fourth space), such that they have airtightness.

And, the air cleanliness in the third space S3 and fourth space S4 is maintained so as to be substantially equal (or such that cleanliness is higher in the fourth space S4 than in the third space S3).

Further, the fourth space S4 is maintained at somewhat higher pressure than the third space S3.

Front-face apertures 16 for the insertion and removal of the airtight covers 83 of the respective wafer-accommodating cassettes 80 are formed in the front-face partitions 15 arranged in the front faces of the multilevel shelves 5, 5, at positions corresponding to each of the cassette placement positions 5c.

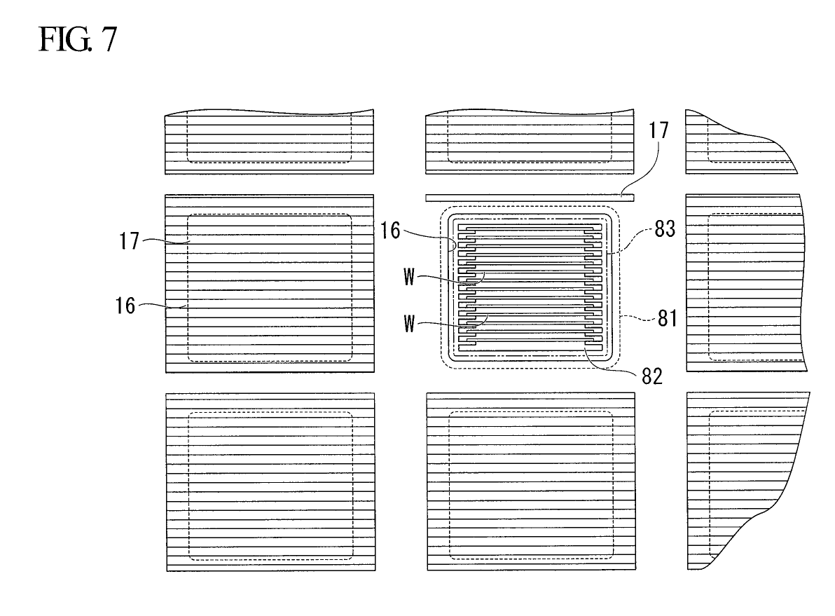

FIG. 7 is a schematic diagram showing front-face apertures 16.

Front-face apertures 16 are formed so as to be larger than airtight covers 83, and smaller than container bodies 81. As explained below, this is in order to press the container body 81 against the inner-peripheral edge of the front-face aperture 16, so as to maintain airtightness of the third space S3 and fourth space S4.

And, shutters 17 are provided for each of the front-face apertures 16; since the front-face apertures 16 are blocked by means of these shutters 17, the third space S3 and fourth space S4 are partitioned with airtightness maintained.

The shutters 17 are opened and closed according to instructions from the control portion 50.

Each of the cassette placement positions 5c of the multilevel shelves 5, 5 is demarcated by internal partitions 18. That is, each cassette placement position 5c is separately sealed by shelf panels 19 (floor and ceiling), front-face partition 15 (shutter 17), rear-face partition 12 (shutter 14), and internal partitions 18.

And, in each of the sealed cassette placement positions 5c is provided an air purge mechanism (not shown).

On the other hand, on the rear-face sides of the multilevel shelves 5, 5, the air purge mechanisms prevent intrusion into the third space S3 of particles and contaminants which exist in the first space when a wafer-accommodating cassette 80 is transported from the first space S1 to a cassette placement position 5c (the third space S3), or when a wafer-accommodating cassette 80 is transported to the first space S1, by a cassette transport portion 30. In particular, particles and contaminants adhering to a wafer-accommodating cassette 80 which has been carried in are eliminated.

Specifically, in order to carry a wafer-accommodating cassette 80 into or out of a cassette placement position 5c, the shutter 14 provided on the rear-face aperture 13 of the rear-face partition 12 is opened, and simultaneously, air or an inflammable gas of high air cleanliness (approximately class 1) is blown into the cassette placement position 5c from the air purge mechanism. In this way, particles and contaminants are eliminated from the cassette placement position 5c, and are caused to be discharged into the first space S1.

By this means, even when the airtight cover 83 of a wafer-accommodating cassette 80 is opened, and an accommodated wafer W is removed, contamination of the wafer W by particles and contaminants can be avoided.

Next, a method of storage management in a storage facility for wafers 1 is explained. Explanations are given in the order of sorting processing, in which interchange of wafers W is performed; tasks of carrying-in of wafer-accommodating cassettes 80; and tasks of carrying-out of wafer-accommodating cassettes 80.

Sorting processing to perform interchange of wafers W among the plurality of wafer-accommodating cassettes 80 accommodated by the storage facility for wafers 1 (the plurality of cassette placement positions 5c of the multilevel shelves 5, 5) is performed by means of the following processes.

Wafer-accommodating cassettes 80, in which are accommodated in advance a plurality of wafers W, are placed at a plurality of cassette placement positions 5c of the multilevel shelves 5, 5. Information relating to each of the wafer-accommodating cassettes 80, and information relating to the wafers W accommodated by each of the wafer-accommodating cassettes 80, is stored in advance in the wafer information storage portion 52 of the control portion 50.

First, the control portion 50 decides, based on commands from a manufacturing line control device, not shown, which executes comprehensive control of a manufacturing line in which the storage facility for wafers 1 is installed, for which wafers W sorting processing is to be performed by the wafer transport portion 20, among the numerous wafers W accommodated by the plurality of wafer-accommodating cassettes 8 placed on the multilevel shelves 5, 5.

And, information relating to the wafers W for interchange, and information relating to the wafer-accommodating cassettes 80 which are the accommodation source and the accommodation destination for these wafers W, is read from the wafer information storage portion 52 and cassette information storage portion 53; in addition, movement instruction information for the wafer transport portion 20 is computed, and is both stored and is output to the wafer transport portion 20.

The wafer transport portion 20 initiates sorting processing based on commands from the control portion 50.

First, the wafer transport portion 20 moves toward the wafer-accommodating cassette 80 in which are accommodated the wafers W for interchanging.

Then, the wafer transport portion 20 controls the traveling portion 22 and main portion 23 to move such that the opener 25 is opposed to the cassette placement position 5c at which is placed the wafer-accommodating cassette 80 for processing.

Next, based on a command from the control portion 50, the shutter 17 which had been blocking the front-face aperture 16 in the front-face partition 15 opens. Then, the moveable portion 25b of the opener 25 is actuated, and the gripping portion 25a comes into close contact with and grips (or suction-clamps) the airtight cover 83 of the wafer-accommodating cassette 80. Then the moveable portion 25b is again actuated, and the airtight cover 83 is removed from the wafer-accommodating cassette 80 and is removed from the third space S3 to the fourth space S4.

When a wafer-accommodating cassette 80 is placed in a cassette placement position 5c of the multilevel shelves 5, 5, or when a shutter 17 of the front-face aperture 16 opens, the container body 81 is fixed in close contact with the inner-peripheral edge of the front-face aperture 16 of the front-face partition 15. Then, with the container body 81 in close contact with the front-face aperture 16, the airtight cover 83 is removed from the wafer-accommodating cassette 80.

By this means, the intrusion of air from the third space S3 into the fourth space S4 is prevented. This is particularly advantageous when particles and contaminants remain in the third space S3.

Mechanisms may be provided in each of the cassette placement positions 5c of the multilevel shelves 5, 5 such that, when a container body 81 comes into close contact with a front-face aperture 16, the container body 81 is pressed toward the front-face aperture 16; or, the container body 81 may be pressed against the front-face aperture 16 by the opener 25.

Next, the wafer transport portion 20 controls the wafer loader 24, traveling portion 22, and main portion 23, to cause the hand 24b connected to the arm portion 24a of the wafer loader 24 to move toward the wafer-accommodating cassette 80 the airtight cover 83 of which has been removed. And, the hand 24b is caused to advance from the front-face aperture 82 of the wafer-accommodating cassette 80 into the container body 81 and to grip the desired wafer W.

Upon gripping the desired wafer W, the hand 24b is retracted from the wafer-accommodating cassette 80, and the opener 25 is again moved toward the wafer-accommodating cassette 80. Then, the airtight cover 83 gripped by the opener 25 is pressed against the container body 81, and the airtight cover 83 is installed on the wafer-accommodating cassette 80.

Then, the opener 25 is retracted from the wafer-accommodating cassette 80, and the front-face aperture 16 of the front-face partition 15 is blocked by the shutter 17.

In this way, the desired wafer W can be extracted from the wafer-accommodating cassette 80 placed at an arbitrary cassette placement position 5c of an arbitrary multilevel shelf 5.

Next, gripping the wafer W placed on the hand 24b of the wafer loader 24, the wafer transport portion 20 moves toward the accommodation-destination wafer-accommodating cassette 80.

Then, through a process similar to that described above, the desired wafer W is accommodated in the accommodation-destination wafer-accommodating cassette 80.

When sorting processing of the desired wafer W is completed, this information is stored in the wafer information storage portion 52 and cassette information storage portion 53 of the control portion 50. Then the next sorting processing is begun, and by repeating the above-described sorting process, only the desired wafers W are accommodated in the desired wafer-accommodating cassette 80.

Carrying-in (storage) of a wafer-accommodating cassette 80 to the storage facility for wafers 1 (multilevel shelf 5) is performed by the following processes.

First, the wafer-accommodating cassette 80 in which are accommodated a plurality of wafers W is carried in from the rear face 5b of a multilayer shelf 5 to a prescribed cassette placement position 5c by the cassette transport portion 30. Position information for the cassette placement position 5c at which the wafer-accommodating cassette 80 is to be accommodated is sent from the control portion 50 to the cassette transport portion 30.

When the wafer-accommodating cassette 80 is gripped by the hand 33 of the cassette transport portion 30, and the wafer-accommodating cassette 80 is moved to the vicinity of the prescribed cassette placement position 5c, the shutter 14 which had been blocking the rear-face aperture 13 of the rear-face partition 12 is opened, based on a command from the control portion 50. Simultaneously, the air purge mechanism begins to operate.

Next, the articulated robot 32 of the cassette transport portion 30 is controlled to place the wafer-accommodating cassette 80 at a cassette placement position 5c of a multilevel shelf 5. And, the grip of the hand 33 is released, and the hand 33 is retracted from the cassette placement position 5c, upon which the shutter 14 blocks the rear-face aperture 13. Simultaneously, the air purge mechanism halts.

In this way, a wafer-accommodating cassette 80 is carried into and accommodated at an arbitrary cassette placement position 5c of a multilevel shelf 5. And, during this carrying-in and accommodation task, the air purge mechanism is operating, so that intrusion of particles and contaminants existing in the first space S1 into the third space S3 (second space S2) is prevented.

The information such as ID number of a wafer-accommodating cassette 80 carried into a multilevel shelf 5, the ID numbers of the wafers W accommodated by the wafer-accommodating cassette 80, and the like is input to the input portion 51 of the control portion 50 prior to carrying-in and accommodation tasks.

An RFID and barcode are affixed to the container body 81 of a wafer-accommodating cassette 80, and prior to carrying-in to a multilevel shelf 5, the RFID and barcode are read by a reader, not shown, installed on the outside of the storage facility main unit 2.

From this RFID and barcode are read the ID number of the wafer-accommodating cassette 80, the ID numbers of wafers W accommodated by the wafer-accommodating cassette 80, and the like, from a manufacturing line control device, not shown, which executes comprehensive control of the manufacturing line at which the storage facility for wafers 1 is installed; this information is input to the input portion 51 of the control portion 50.

Carrying-out of a wafer-accommodating cassette 80 from the storage facility for wafers 1 (multilevel shelf 5) is performed according to the following processes.

First, information on the wafer-accommodating cassette 80 to be carried out (multilevel shelf 5, position information of the cassette placement position 5c, and the like) is sent from the control portion 50 to a cassette transport portion 30. The cassette transport portion 30 approaches the rear face 5b of the prescribed multilevel shelf 5, and moves the hand 33 toward the prescribed multilevel shelf 5.

Next, in response to a command from the control portion 50, the shutter 14 which had been blocking the rear-face aperture 13 of the rear-face partition 12 opens, and at the same time the air purge mechanism begins to operate.

And, the articulated robot 32 is controlled to move the hand 33 within the third space S3; the wafer-accommodating cassette 80 is gripped from the rear-face side and is moved toward the first space S1.

Then, the wafer-accommodating cassette 80 is placed on the unmanned vehicle 31. The cassette transport portion 30 controls the unmanned vehicle 31 to begin moving toward the desired processing device.

When the wafer-accommodating cassette 80 is carried out from the cassette placement position 5c (third space S3), in response to a command from the control portion 50, the shutter 14 blocks the rear-face aperture 13, and simultaneously the air purge mechanism stops.

In this way, the desired wafer-accommodating cassette 80 is carried out from an arbitrary cassette placement position 5c of an arbitrary multilevel shelf 5. And, during this carrying-out task, the air purge mechanism is operating, so that intrusion into the third space S3 (second space S2) of particles and contaminants existing in the first space S1 is prevented.

The above-described sorting processing of wafers W and carrying-in and carrying-out tasks of wafer-accommodating cassettes 80 can each be performed separately, independently, and simultaneously, so long as tasks do not overlap for the same wafer-accommodating cassette 80.

Further, at a multilevel shelf 5 of the storage facility for wafers 1, wafer-accommodating cassettes 80 can be directly carried into and out of each cassette placement position 5c. Hence a wafer-accommodating cassette 80 for which sorting of wafers W has been completed can be carried out from a multilevel shelf 5 when appropriate. Also, a wafer-accommodating cassette 80 for which sorting processing is to be performed can be carried into an unoccupied cassette placement position 5c when appropriate.

Further, wafer-accommodating cassettes 80 can be carried into and carried out of a multilevel shelf 5 simultaneously by a plurality of cassette transport portions 30.

Thus in the storage facility for wafers 1, sorting processing of wafers W between wafer-accommodating cassettes 80 can be performed efficiently, and at the same time carrying-in and carrying-out of wafer-accommodating cassettes 80 to and from multilevel shelves 5 can also be performed efficiently.

The operation procedures, as well as the various shapes and combinations of constituent members and other details of the above-described embodiment are examples, and various modifications are possible based on process conditions and design requirements without deviating from the gist of the invention.

For example, in the explanation of the above-described embodiment, a single traveling portion 22 (wafer loader 24 and the like) was arranged on rails 21 of the wafer transport portion 20; but the wafer transport portion 20 is not limited to such a configuration. By arranging a plurality of traveling portions 22 (wafer loaders 24 and the like) on the rails 21, sorting of wafers W can be performed more efficiently.

Also, the number of wafer loaders 24 connected to one traveling portion 22 is not limited to one, and a plurality of wafer loaders 24 may be connected.

Also, the wafer transport portion 20 is not limited to a mode of travel over rails 21 on the floor, and a mode of traveling in a state of suspension from the ceiling may be employed.

Also, similarly to the cassette transport portions 30, the wafer transport portion 20 may employ an unmanned vehicle not requiring straight rails.

The cassette transport portion 30 is not limited to a mode in which an articulated robot 32 is installed on an unmanned transport vehicle 31. For example, similarly to the wafer transport portion 20, a mode of travel on rails may be employed.

As the cassette transport portions 30, a transport system which is in close contact with a multilevel shelf 5 to carry in and out a wafer-accommodating cassette 80 to and from the multilevel shelf 5, and a transport system which transports a wafer-accommodating cassette 80 in the direction away from a multilevel shelf 5, may exist separately and independently.

Also internal partitions 18 are not essential, so that air purges of the whole third space may be performed by means of the air purge mechanism.

In place of an unmanned transport vehicle 31, the cassette transport portion 30 may use a ceiling-traveling car. That is, a horizontal-transport mechanism which moves wafer-accommodating cassettes 80 in horizontal directions may be provided at each of the cassette placement positions 5c of the multilevel shelves 5, 5. By this means, wafer-accommodating cassettes 80 transported by the horizontal-transport mechanism may be gripped and transported from cassette placement positions 5c by ceiling-traveling cars provided above on the sides of the rear faces 5b, 5b of the multilevel shelves 5, 5, and by articulated robots 32 and hands 33 connected to the ceiling-traveling cars.

In the above-described embodiment, a case was explained in which partitions 15, 12, apertures 16, 13, and shutters 17, 14 are provided on the front faces 5a and rear faces 5b respectively of the multilevel shelves 5, 5; however, the multilevel shelves 5, 5 are not limited to this configuration. Any configuration may be adopted which is capable of preventing the intrusion into the fourth space S4 of particles and similar adhering to wafer-accommodating cassettes 80, causing contamination of wafers W.

As explained above, when the container body 81 of a wafer-accommodating cassette 80 is fixed in close contact with the inner-peripheral edge of a front-face aperture 16 of a front-face partition 15, the intrusion of particles and similar from the third space S3 into the fourth space S4 can be prevented, and so front-face partitions 15, and shutters 17 to block front-face apertures 16, are not indispensable.

Further, when partitions 15, 12, apertures 16, 13, and shutters 17, 14 are provided on the front faces 5a and rear faces 5b of the multilevel shelves 5, 5, and in addition, air purge mechanisms are provided in the third space S3, the intrusion of particles and similar from the third space S3 into the fourth space S4 can be prevented, so that the fixing in close contact of the container bodies 81 of wafer-accommodating cassettes 80 with the inner-peripheral edges of the front-face apertures 16 of the front-face partitions 15 is not indispensable.

In the above-described embodiment, a case was explained of application to semiconductor wafers, but use with other substrates is possible. For example, application to glass substrates for FPDs, and other plate-shape members, is possible.

### INDUSTRIAL APPLICABILITY

By means of this invention, when a plurality of substrates are accommodated in cassettes, and cassettes are individually transported and accommodated in an automated warehouse, substrate interchange processing can be performed efficiently, and at the same time cassette carrying-in and carrying-out processing can also be performed efficiently. Moreover, the possibility of adhesion of contaminating matter to substrates can be reduced, so that declines in production yields can be avoided.

1. A substrate storage facility, comprising:
a multilevel shelf, on which a plurality of cassettes with airtight covers accommodating a plurality of substrates can be placed;
a substrate transport portion, moveably positioned on the front-face side of said multilevel shelf, which opens and closes the airtight covers of said cassettes with airtight covers placed on said multilevel shelf, and which transports said substrates between said cassettes with airtight covers; and,
a cassette transport portion, moveably positioned on the rear-face side of said multilevel shelf, which carries said cassettes with airtight covers into and out of all of the cassette placement positions of said multilevel shelf.

2. The substrate storage facility according to claim 1, wherein said multilevel shelf comprises a rear-face partition, partitioning into a first space, in which said cassette transport portion is positioned, and a second space, in which said multilevel shelf and said substrate transport portion are positioned; rear-face apertures, formed at positions in opposition to each of said cassette placement positions in said rear-face partition, via which said cassettes with airtight covers are carried in and out; and, first airtight doors, which block said rear-face apertures.

3. The substrate storage facility according to claim 2, wherein said first space and said second space are maintained in different air states.

4. The substrate storage facility according to claim 1, wherein said multilevel shelf comprises a front-face partition, partitioning into a third space in which said multilevel shelf is positioned and a fourth space into which said substrate transport portion is positioned; front-face apertures, formed at positions in opposition to each of said cassette placement positions in said front-face partition, via which said substrates are carried into and out from said cassettes with airtight covers; and, second airtight doors, which block said front-face partitions.

5. The substrate storage facility according to claim 1, wherein said cassettes with airtight covers are placed on said multilevel shelf such that the body of said cassette with an airtight cover is fixed in close contact with the inner-peripheral edge of said front-face aperture.

6. The substrate storage facility according to claim 4, wherein said third space and said fourth space are maintained in different air states.

7. The substrate storage facility according to claim 1, wherein said multilevel shelf has internal partitions which demarcate said cassette accommodation positions, individually or into a plurality.

8. The substrate storage facility according to claim 4, wherein said multilevel shelf comprises an air purge mechanism which performs air purges of said third space when said cassettes with an airtight cover are carried into or out of said multilevel shelf.

9. The substrate storage facility according to claim 1, wherein multilevel shelves are arranged in opposition on either side of said substrate transport portion, and such that said cassette transport portion is arranged for each of said multilevel shelves.
